(19) United States
(12) Patent Application Publication
(10) Pub. No.: US 2011/0030763 A1
(43) Pub. Date: Feb. 10, 2011

(54) Solar Panel Apparatus Created By Laser Etched Gratings on Glass Substrate

(76) Inventor: Jeffrey Lewis, Tijeras, NM (US)

Correspondence Address: MICHAEL E. KLICPERA, PO BOX 573, LA JOLLA, CA, 92038-0573, US

(21) Appl. No.: 12/537,560

(22) Filed: Aug. 7, 2009

(51) Int. Cl. H01L 31/052; H01L 21/302; G02B 5/32

(52) U.S. Cl. 136/246; 438/707; 359/15; 257/E21.214

(57) ABSTRACT

The present invention fabrication method and apparatus provides a method of creating holographic configurations in a specific pattern in glass panels using a laser that does not use chemicals or chemical solutions.

### FIELD OF THE INVENTION

The field of art to which this invention relates is in the method of fabricating holographic configurations in glass structures without the use of chemical solutions whereby the holographic configuration functions to deflect certain wavelengths of light and focus other wavelengths of light. More specifically, the present invention is method and apparatus for defecting IR and near IR wavelength and focusing visible light wavelength to increase the efficiency of a solar panel.

### BACKGROUND OF THE INVENTION

During the conversion of solar energy to electricity by a semiconductor photovoltaic cell, incident photons free bound electrons, allowing the electrons to move across the photovoltaic cell. In this process, a photon having energy less than the photovoltaic material's band gap is not absorbed, while a photon having energy greater than the photovoltaic material's band gap only contributes the band gap energy to the electrical Output, and excess energy is lost as heat affecting the efficiency of the solar cell.

Thus, a given photovoltaic cell operates most efficiently when exposed to a narrow spectrum of light whose energy lies just above the photovoltaic material's band gap.

To achieve higher solar energy conversion efficiency than can be obtained with a single photovoltaic material, a number of techniques have been developed to split the broad solar spectrum into narrow components and direct those components to appropriate photovoltaic cells.

In U.S. Pat. No. 2,949,498 to Jackson (1960), a solar energy converter is disclosed that splits the solar spectrum by stacking photovoltaic cells. A high band gap photovoltaic cell is placed in front of one or more photovoltaic cells having successively lower band gaps. High energy photons are absorbed by the first cell and lower energy photons are absorbed by the following cell. This method is disadvantageous in that the leading cells must be made transparent to the radiation intended for the following cells.

Ludman et al., Proceedings of the Twenty-fourth IEEE Photovoltaic Specialists Conference, pp. 1208-1211 (1994), describes a design in which the spectrum is split by diffraction, and different photovoltaic cells are arranged to capture light of different wavelengths. A hologram serves as the diffraction grating and also concentrates the sunlight. This method is disadvantageous in that it is difficult to economically create durable diffraction gratings having high optical efficiency over a wide portion of the solar spectrum.

While refractive dispersion is a well known means of separating light into its spectral components, it is not trivial to create a refractive optical arrangement that is suitable for solar energy conversion. For example, refractive dispersion designs using only a single array of prisms or a concentrator with a single dispersing prism at or near its focus do not simultaneously provide adequate dispersion and concentration. In U.S. Pat. No. 4,021,267 to Dettling discloses a spectrum splitting arrangement comprising concentrating, collimating, and refractive dispersing means. This method is disadvantageous in that the collimating optical element introduces additional transmission losses and alignment difficulties.

In U.S. Pat. No. 6,015,950 to Converse discloses a solar energy conversion system, in which two separated arrays of refracting elements disperse incident sunlight and concentrate the sunlight onto solar energy converters, such that each converter receives a narrow portion of the broad solar spectrum and thereby operates at higher efficiency.

Conventional holographic gratings are usually created by a photographic process wherein a glass substrate is coated with a photoresist. The exposed plate is then developed using chemicals.

Prism Solar Technologies, markets a solar panel design which includes a polymeric holographic panel sandwiched between two panels of glass. The holographic gratings and etches created using this conventional method of manufacturing do not have a long working life based on the chemicals and the polymeric substrates used. Many, if not most of the chemicals used for this grating and etching process are not environmentally friendly.

The present invention process and apparatus enables an environmentally friendly method of creating holographic gratings that are conveniently installed or are incorporated in standard solar cell designs and will outlast the equipment that they are installed into.

Notwithstanding the known problems and attempts to solve these problems, the art has not adequately responded to date with the introduction of a solar energy which improves efficiency by deflecting undesirable wavelengths and focusing the wavelengths corresponding to the photovoltaic material's band gap.

### SUMMARY OF THE INVENTION

The present invention fabrication method uses a titanium sapphire (Ti-Sapphire) ultrafast laser (femtosecond output beam) directed through an optics focusing assembly onto a glass substrate. The beam characteristics of the Ti-Sapphire laser used interact non-linearly with the glass substrate and cause ablation of the glass in a manner that enables the creation of a grating structure without the thermal damage usually encountered when using slower lasers to write to a substrate in this manner. By utilizing galvanometers, and X-Y stage or other positioning systems, custom holographic gratings or images can be created at a very low cost without the use of any chemicals. The holographic gratings can be created that are suitable for use in infra-red, visible and even ultra violet light applications.

Applications using Damien gratings, dot matrix gratings or line gratings as well a multiplex holography can be created using this technology. The present application is for the solar industry where the infrared component can be reflected or canceled while the visible component is concentrated onto the solar cells. Various lines and dot sizes can be directly written onto a glass substrate using the setup shown in the graphic herein.

### BRIEF DESCRIPTION OF THE DRAWINGS

FIG. 1 is a perspective representation of the laser apparatus etching a holographic focusing or deflection etched grating pattern into a glass panel.

FIG. 2 is a perspective representation of the present invention etched in a glass panel engaged to a typical solar panel.

FIG. 3 is a front view of the present invention glass panel having a plurality of circular etched gratings.

FIG. 4 is a sectional side view taken from FIG. 3 demonstrating in more detail a first depth of the circular etched gratings.

FIG. 5 is a sectional side view taken from FIG. 3 demonstrating in more detail a second depth of the circular etched gratings.

FIG. 6 is a front view of the present invention glass panel having other depth of plurality of circular etched gratings.

FIG. 7 is a front view of another embodiment of the present invention glass panel having a plurality lines etched gratings.

FIG. 8 is a side cross sectional of the present invention showing the depth of plurality grating lines etched in a glass panel.

FIG. 9 is a side cross sectional of another embodiment of the present invention demonstrating a holographic glass panel that has both a grating line and plurality of circular gratings etched in a glass panel.

FIG. 10 is a color photomicrograph of the Ti-Sapphire laser creating a 9.14 um spot size matrix on BK7 substrate.

FIG. 11 is a color photomicrograph of the Ti-Sapphire laser creating a 16.44 um spot size matrix on BK7 substrate.

FIG. 12 is a color photomicrograph of the Ti-Sapphire laser creating a 7.35 um line on 100 um center on BK7 substrate.

FIG. 13 is a color photomicrograph of the Ti-Sapphire laser creating a 21.53 um spot size matrix on BK7 substrate.

FIG. 14 is a color photomicrograph of the Ti-Sapphire laser creating a 49.02 um spot size matrix on BK7 substrate.

FIG. 15 is a color photomicrograph of the Ti-Sapphire laser creating a 67.05 um spot size matrix on BK7 substrate.

FIG. 16 is a color photomicrograph of the Ti-Sapphire laser creating a 99.40 um spot size matrix on BK7 substrate.

### DESCRIPTION OF THE PREFERRED EMBODIMENTS

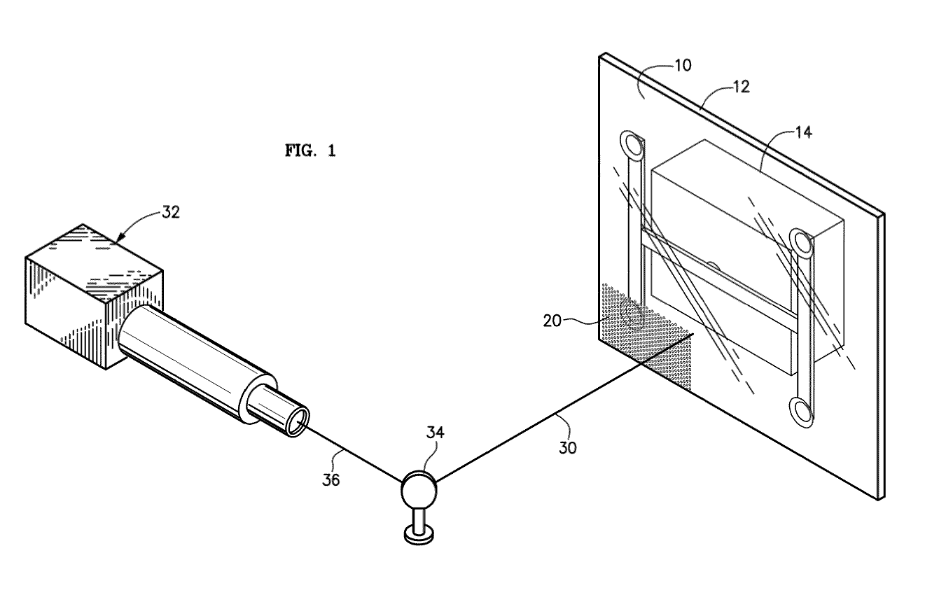

As shown in FIG. 1, the present invention fabrication method utilizes a Ti:sapphire ultrafast laser 32 (also known as Ti:Al₂O₃ lasers, titanium-sapphire lasers, or simply Ti:sapphs) that are tunable or adjustable lasers which emit red and near-infrared light 36 in the range from 650 to 1100 nanometers. The Ti:sapphire laser 32 is desirable for its capability to allow certain adjustability and have the ability to generate ultrashore pulses. The defined name of the laser as a Titanium-sapphire refers to the lasing medium, a crystal of sapphire (Al₂O₃) that is doped with titanium ions. A Ti:sapphire laser is sometime coupled with another laser with a wavelength of 514 to 532 nm, for which argon-ion lasers (514.5 nm) and frequency doubled e.g. Nd:YAG lasers (527-532 nm) are used. Ti:sapphire lasers operate most efficiently at wavelengths near 800 nm.

Mode-Locked Oscillators

Mode-locked oscillators generate ultrashort pulses with a typical duration between 10 femtoseconds and a few picoseconds, in special cases even around 5 femtoseconds. The pulse repetition frequency is in most cases around 70 to 90 MHz. Ti:sapphire oscillators are normally pumped with a continuous-wave laser beam from an argon or frequency-doubled e.g. Nd:YVO4 Nd:YVO4 laser.

Chirped-Pulse Amplifiers

Chirped-pulse amplifier lasers generate ultra-short, ultra-high-intensity pulses with a duration of 20 to 100 femtoseconds. A typical one stage amplifier can produce pulses of up to 5 millijoules in energy at a repetition frequency of 1000 hertz, while a larger, multistage facility can produce pulses up to several joules, with a repetition rate of up to 10 Hz. Usually, amplifiers crystals are pumped with a pulsed frequency-doubled Nd:YLF laser at 527 nm and operate at 800 nm. Two different designs exist for the amplifier: regenerative amplifier and multi-pass amplifier.

Regenerative amplifiers operate by amplifying single pulses from an oscillator (as described above). Instead of a normal cavity with a partially reflective mirror, they contain high-speed optical switches that insert a pulse into a cavity and take the pulse out of the cavity exactly at the right moment when it has been amplified to a high intensity. The term ‘chirped-pulse’ refers to a special construction that is necessary to prevent the pulse from damaging the components in the laser.

In a multi-pass amplifier, there are no optical switches. Instead, mirrors guide the beam a fixed number of times (two or more) through the Ti:sapphire crystal with slightly different directions. A pulsed pump beam can also be multi-passed through the crystal, so that more and more passes pump the crystal. First the pump beam pumps a spot in the gain medium. Then the signal beam first passes through the center for maximal amplification, but in later passes the diameter is increased to stay below the damage threshold, to avoid amplification of the outer parts of the beam, thus increasing beam quality and cutting off some amplified spontaneous emission and to completely deplete the inversion in the gain medium. The pulses from chirped-pulse amplifiers are often converted to other wavelengths by means of various nonlinear optics processes.

At 5 mJ in 100 femtoseconds, the peak power of such a laser is 50 gigawatts, which is many times more than what a large electrical power plant delivers (about 1 GW). When focused by a lens, these laser pulses will destroy any material placed in the focus, including air molecules.

When a laser pulse passes an electron the electron is shaken heavily, but afterwards it flies on as if nothing has happened, though a little bit of Compton scattering has taken place. Additionally an electron can either enter or leave an atom and in this process the electron can either emit an X-ray photon or absorb an X-ray photon. In a complex situation with an atom, an electron, and a laser pulse, either the energy of the X-ray photon depends on the electric field of the laser pulse at the time of creation or the energy of the electron depends on the electric field of the laser pulse at the time of leaving the atom. This is called either pulsed X-ray generation or attosecond transient recorder.

The present invention fabrication methods employs a Ti:sapphire laser system 32 that includes the capability to adjust the 1) power, 2) repetition rates and pulse waves (pulse width) and 3) duration. The Ti:sapphire laser system 32 can include one or more laser light lines 36 that are reflected by a laser mirror 34 that redirected the reflected laser light 30 to an object, such as the glass panel 10. By adjusting the parameters described above, the present invention fabrication method is capable of creating certain gratings and etching structures 20 on the upper, and/or the under surface of a glass panel 10. In addition, the present invention fabrication method can create these certain gratings and etching structures within the interior regions 12 of the glass panel 10. Hence, the present invention fabrication method can create multiple layers of gratings and etching structures 20 within and on the glass panel 10 to provide specific wavelength rejection and focusing properties. As shown in FIG. 1, the glass panel 10 is advanced using a controlled movement system 14 such that substantially its entire surface is exposed to the Ti:sapphire laser adjusted with specific parameters. FIG. 1 is only one example as the present invention fabrication method can employ multiple or movable lasers and sophisticated advancing systems to create the gratings and etching structures on and within the glass panel.

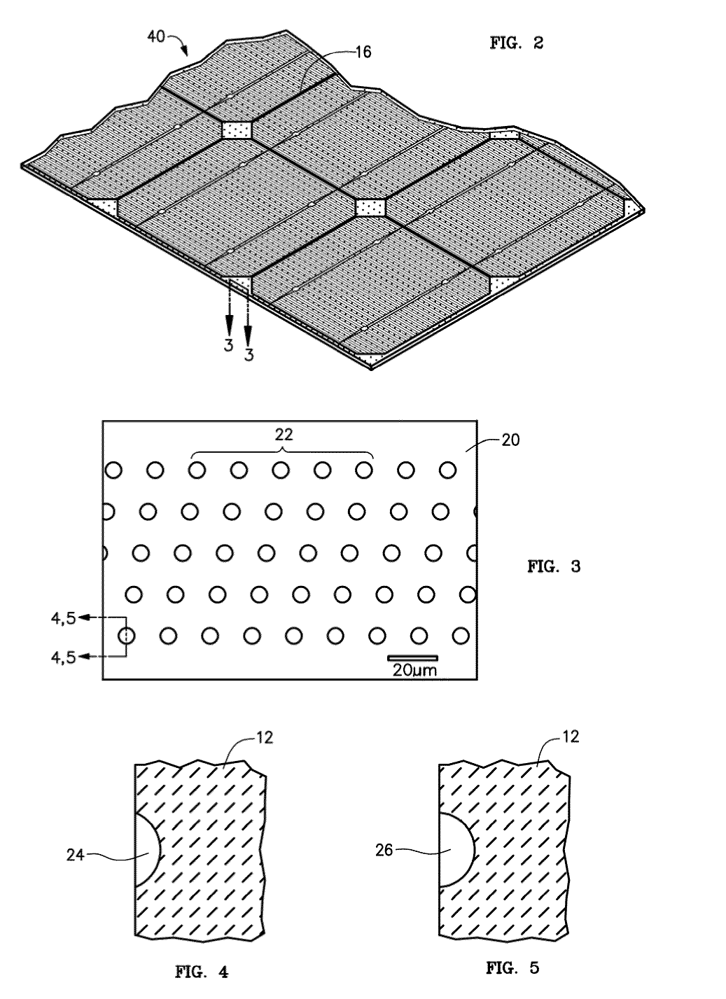

Now turning to FIG. 2, shown is a perspective representation of the present invention holographic etched glass panel engaged to a typical solar panel and a brief description of the technology.

Solar cell panels are well known devices for converting solar radiation to electrical energy. Most, to date, are fabricated on a semiconductor wafer using semiconductor processing technology. Generally speaking, a solar cell may be fabricated by forming p-doped and n-doped regions in a silicon substrate. Solar radiation impinging on the solar cell creates electrons and holes that migrate to the p-doped and n-doped regions, thereby creating voltage differentials between the doped regions. The side of the solar cell where connections to an external electrical circuit are made includes a topmost metallic surface that is electrically coupled to the doped regions. There may be several layers of materials between the metallic surface and the doped regions. These materials may be patterned and etched to form internal structures.

Light is composed of different wavelengths, some having desirable properties and other having undesirable characteristics. Photons generated in the infrared and near infrared regions of the electromagnetic spectrum (wavelengths of approximately 10⁻⁵) are not readily absorbed by the PV cell and release their energy in the form of heat. Heat has a negative effect on PV efficiency where, at standard temperature, a 1.0° C. rise in temperature decreases the PV efficiency approximately 0.1%. In a typical operation, a solar cell temperature can rise from 5 to 100 degrees Fahrenheit. This range of the temperature rise depends on the environment (cold vs. hot environments) and construction of the panel. Solar PV cells are designed to utilize photons generated from the visible light region (400 nm to 800 nm) of the electromagnetic spectrum and focusing of these light waves can have a positive effect on PV cell efficiency. The present invention modified holographic glass panel 16 with specific gratings and etchings is designed to replace the typical standard glass covering on a solar cell panel that results in a modified solar cell panel 40 having a holographic glass panel 16 positioned over the solar cell that functions to: 1) deflect the heat generated by infrared and near infrared light wavelengths; and/or 2) focus the photons from the visible light region onto the PV cells.

FIG. 3 is a front view of a first embodiment of the present invention glass panel having a plurality of circular etched gratings 22. The etched gratings 22 are shown in this FIG. 3 as regular pattern on a glass sheet. The etch grating 22 can be organized to obtain a particular configuration which may not be in a regular pattern but rather designed for a particular application (e.g. focusing light rays over solar cell areas). The circular etched gratings 22 can be etched by the Ti:sapphire laser system 32 on the upper surface, the under surface, or can be embedded within the interior thickness of the glass sheet. As demonstrated in the Experiment section provided herein, the diameter of the individual circular etched gratings 22 range from 5 micrometers to 200 micrometers with a preferred diameter range from 9 micrometers to 99 micrometers. The areas separating the individual circular etched gratings 22 can range from a few micrometers to several hundred micrometers. The diameter and pattern or configuration of the individual circular etched gratings 22 can be arranged to achieve various objectives, e.g. to deflect the heat generated by infrared and near infrared light wavelengths and/or focus the photons from the visible light region onto the PV cells.

As shown in sectional side views FIGS. 4 and 5, taken from FIG. 3, the circular etched gratings 22 can be a first depth, as shown in FIG. 4, or be etched to a second depth as shown in FIG. 5. The depth and width shown in FIGS. 4 and 5 can be adjusted for the wavelength of interest and are infinitely variable. As discussed herein, the circular etched gratings can be incorporated on the upper surface, under surface and/or the interior thickness and arranged to achieve various objectives, e.g. to deflect the heat generating by infrared and near infrared light wavelengths and/or focus the photons from the visible light region onto the PV cells. For example, the plurality of circular etched gratings 22 can be arranged in several line patterns that are separated from each other by 2 micrometers on the upper surface of the glass panel, with another plurality of circular etched gratings 22 arranged in several line patterns that are separated from each other by 4 micrometers in the interior thickness of the glass panel, with still another plurality of circular etched gratings 22 arranged in several line patterns that are separated from each other by 8 micrometers on the under surface of the glass panel. These layers of etched circular gratings thereby provide a series of circular etched gratings patterns that can deflect various wavelengths of infrared and near infrared light at the different levels/layers. In addition, the circular etched gratings 22 can be arranged in a certain pattern that results in a holographic configuration which can be used to focus the photons from the visible light region onto the PV cells.

FIG. 6 is a front view of the present invention glass panel having another depth of plurality of circular etched gratings 28 in a regular pattern (shown) or a non-regular defined pattern (not shown) resulting in a etched grating section 20 of the modified glass panel. The other depth of circular etched gratings 28 appears to have several ring structures in each circular etched grating 28. As demonstrated in the Experiment section provided herein, the diameter of the individual circular etched gratings 22 range from 5 micrometers to 200 micrometers with a preferred diameter range from 9 micrometers to 99 micrometers. The areas separating the individual circular etched gratings 22 can range from a few micrometers to several hundred micrometers. The depth and width shown in FIG. 6 can be adjusted for the wavelength of interest and is infinitely variable.

Now referring to FIG. 7 that shows a front view of another embodiment of the present invention glass panel 20 having a plurality of etched grating lines 29. As demonstrated in the Experiment section provided herein, the width of the individual etched grating lines 29 range from 2 micrometers to 50 micrometers with a preferred width ranging from 4 micrometers to 10 micrometers. The plurality of etched grating lines 29 can be arranged in several line patterns that are separated from each other by 2 micrometers on the upper surface of the glass panel, with another plurality of etched grating lines 29 arranged in several line patterns that are separated from each other by 4 micrometers in the interior thickness of the glass panel, with still another plurality of etched grating lines 29 arranged in several line patterns that are separated from each other by 8 micrometers on the under surface of the glass panel. These layers of etched grating lines thereby provide a series of etched grating line patterns that can deflect various wavelengths of infrared and near infrared light at the different levels/layers.

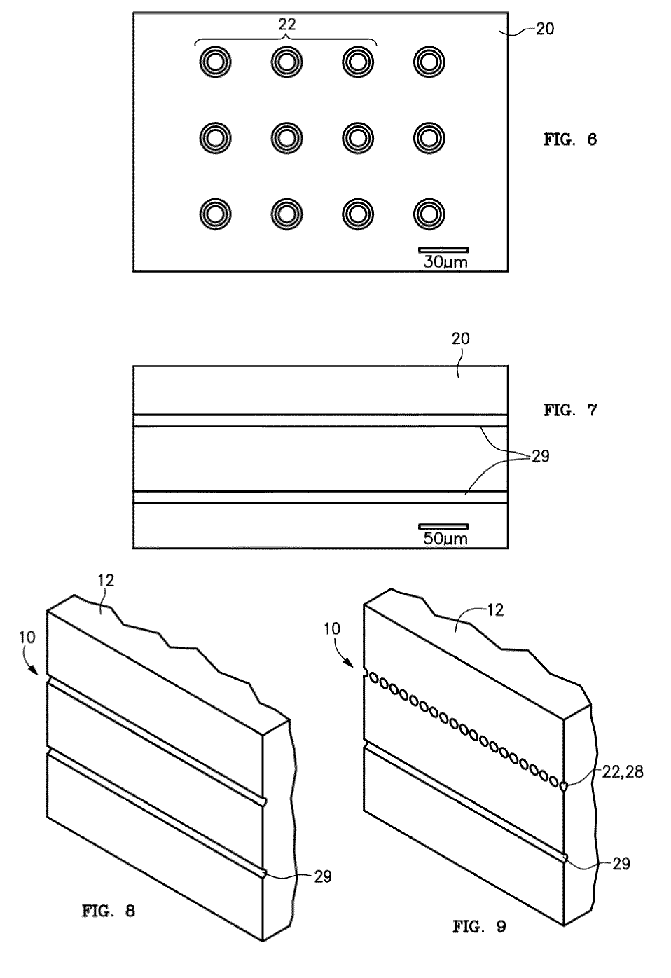

FIG. 8 is a side cross sectional of the present invention showing a plurality holographic grating lines etched in a glass panel. The depth and width shown in FIG. 8 can be adjusted for the wavelength of interest and is infinitely variable.

Shown in FIG. 9 is a side cross sectional of another embodiment of the present invention demonstrated a holographic modified glass panel that has both a grating line and plurality of circular gratings etched in a glass panel.

Glass Panel Enhancement Proposal

### Purpose:

Solar panels manufactured for today's consumer market have an optical to electrical conversion efficiency that ranges from 7% to about 20%. Cells themselves can convert upwards of 23% for the best commercially available multi-junction silicon solar cells. One factor that introduces significant efficiency loss into the system is the absorption of infra-red energy. The loss caused by infra-red energy is approximately −0.1% for every 1 degree Celsius increase in junction temperature. Conservatively speaking, this means that a solar panel in use loses or wastes at least 10% of its power due to thermal heating effects.

### Hypothesis:

It is proposed to implement novel laser technology to minimize the effects caused by thermal loss in a silicon solar system.

1. The experiment will use a novel laser technology to create a holographic grating structure directly in the glass for a permanent solution which would be used on glass (solar panels). Conservative estimates indicate that the conversion efficiency of each glass panel would be increased by approximately 5% to 12%. This holographic grating would also be used to create passive solar tracking concentrators in a parallel product development. Passive solar tracking concentrators utilize multiple holographic exposures to enable constant power output regardless of sun angle. A solar panel manufactured using this approach would utilize 50% less silicon with the same electrical output, thus dramatically lowering the cost of production

2. Materials:

1. Temperature/humidity recorder (Date1) 24/7 continuous
2. Spectrometer, Scanning dual beam uv to nir 2-2 um (to characterize holograms) One for vis, one for IR. 150 nm to 3.0 um. Shimadzu UV3700
3. Beam spreader, concave and parabolic mirror 18″-20″ dia. With f4 or f5 focal length.

### 4. Galaxy Optics 18″ f4.5

### 5. Galaxy Optics 20″

6. Data acquisition system for logging temp/power outputs from test solar panels
7. Shelves/cabinets for storage of optical components and cleaning materials
8. Microscope objectives 3ea. 10×, 20×, 40×CVI optics/melles griot
9. XYZ positioning equipment Opto-Sigma/Daedal Parker?
10. Pinholes, 3 ea. Various size
11. Laser power meter PM130-120
12. Laser power meter Coherent
13. De-ionized water system

### 14. Heat Guns

15. Large vacuum oven
16. Vacuum pump TBD
17. Air compressor
18. Plate holder from Data Optics.
19. Iris diaphragms at least 3ea. Minimum 1 mm dia. opening
20. Laser shutter electric, Uniblitz LS-6 VMM-T1
21. Hot tubs for heating chemicals.
22. Fume hood extractors.
23. Ohaus triple beam balance scale 0-2610 grams

### 24. Large Scale AV2101

### 25. Small Scale AV53

26. Ultrasonic cleaner, Bransonic, B5510, 11.5″×9.5″×6″
27. Ti-Sapphire laser high power fast pulse rep rate—Coherent
28. Ti-Sapphire laser high power fast pulse rep rate—Quantronix
29. Melles Griot Diode laser 85-BLS-601
30. Oscilloscope, 400 Mhz, Analog, Tektronix 2456B 4 channel+4 probes
31. Power supply 0-35 vdc 10 amps, Tenma
32. 6 digit DVM, handheld, Fluke
33. 6 digit DVM, benchtop, Fluke

### 34. Computers Pentium4

35. ZemaxEE optical design software
36. Pulse-Function generator 10 Mhz

Chemicals:
a) Gelatin Knox Bloom 213 and 255
b) ammonium dichromate, crystals, reagent grade
c) Kodak Rapid Fixer, liquid
d) IPA, Isopropyl alcohol, commercial grade
e) IPA, Reagent grade
f) UV curing optical cement for laminating cover glass to finished hologram.
g) UV lamps for curing cement or buy some sun time
h) Glass, water white, low or no iron content.

3. Methods:

This invention uses a titanium sapphire (Ti:Sapphire) ultrafast laser (femtosecond output beam) directed through an optics focusing assembly onto a glass substrate. The beam characteristics of the Ti-Sapphire laser used, interact non-linearly with the glass substrate and cause ablation of the glass in a manner that enables the creation of a grating structure without the thermal damage usually encountered when using slower lasers to write to a substrate in this manner. By utilizing galvanometers, and X-Y stage or other positioning systems, custom holographic gratings or images can be created at a very low cost without the use of any chemicals. The holographic gratings can be created that are suitable for use in infra-red, visible and even ultra violet light applications. Applications using Damien gratings, dot matrix gratings or line gratings as well a multiplex holography can be created using this technology. One application is for the solar industry where the infrared component can be reflected or canceled while the visible component is concentrated onto the solar cells.

4. Results:

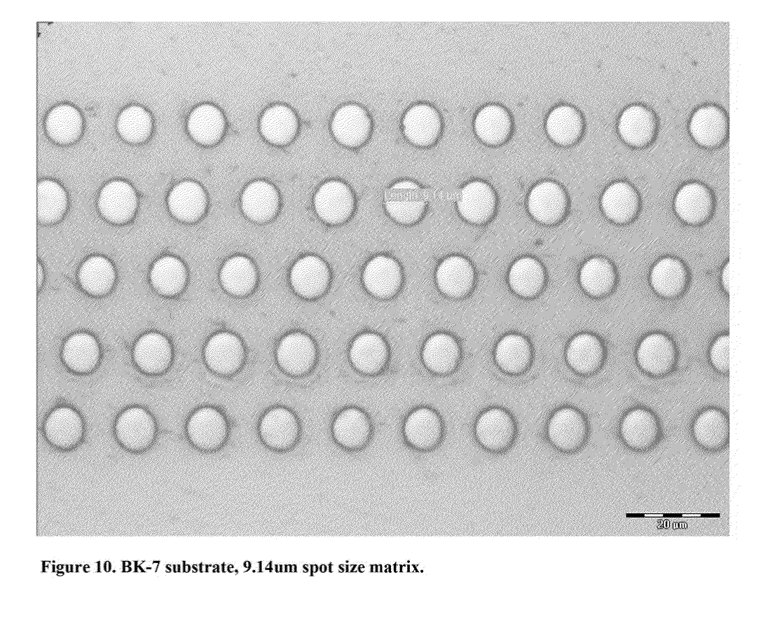

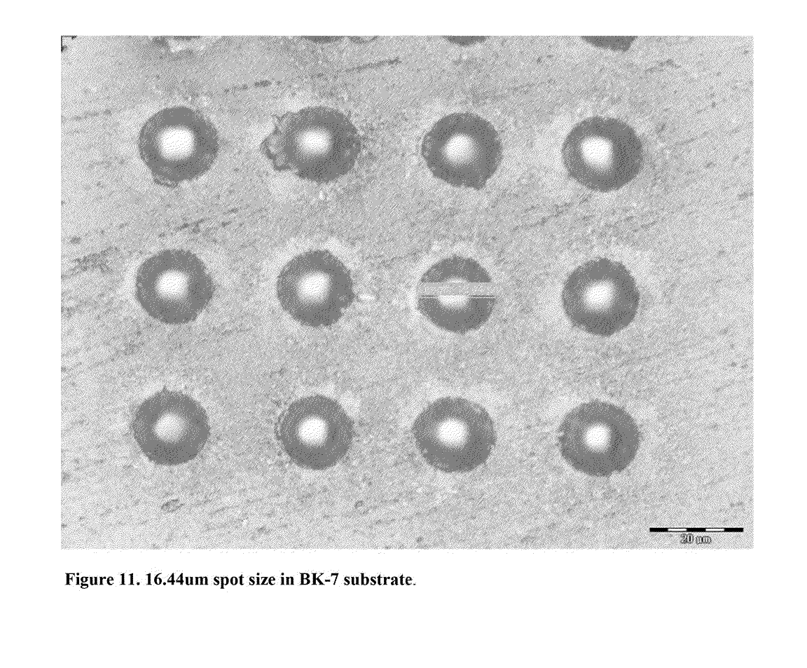

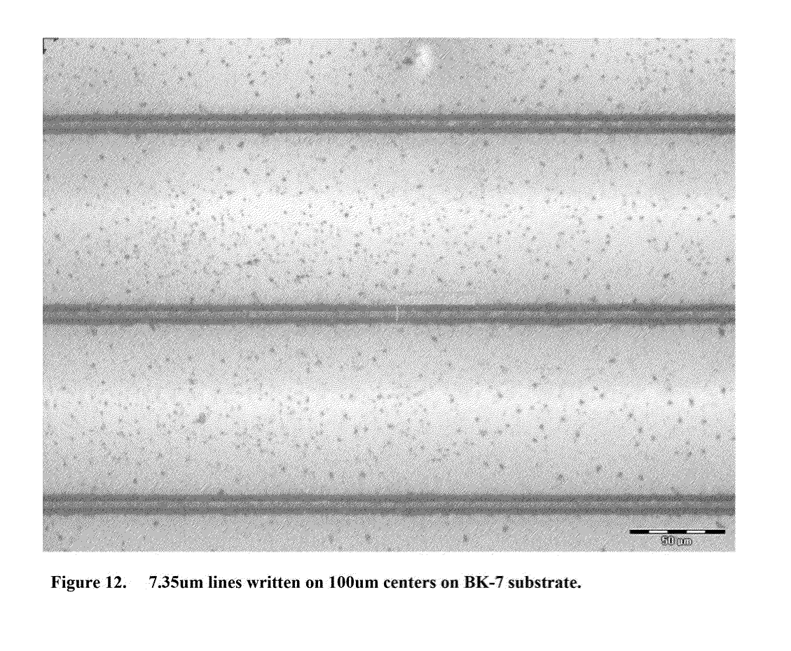

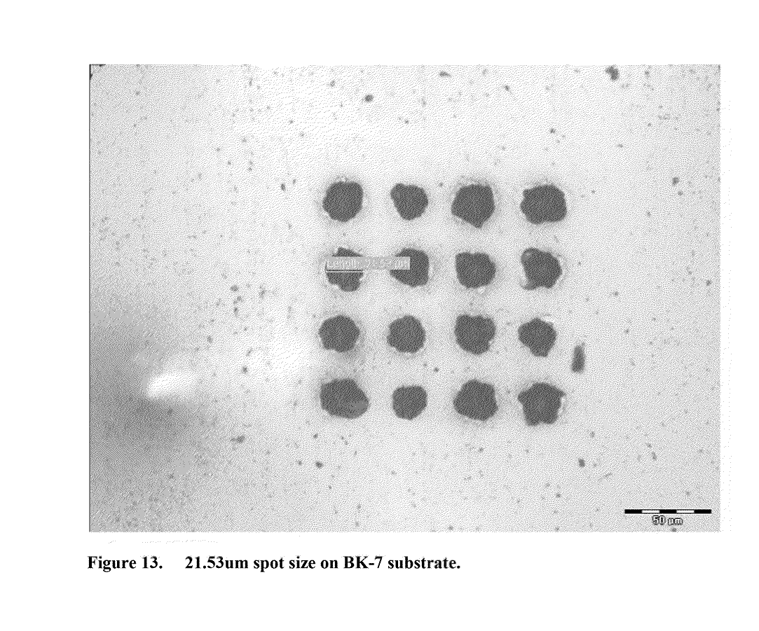

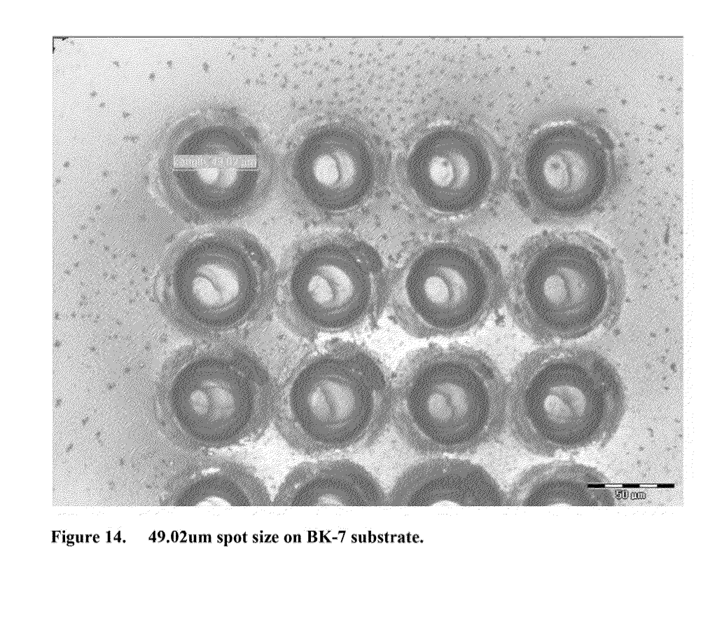

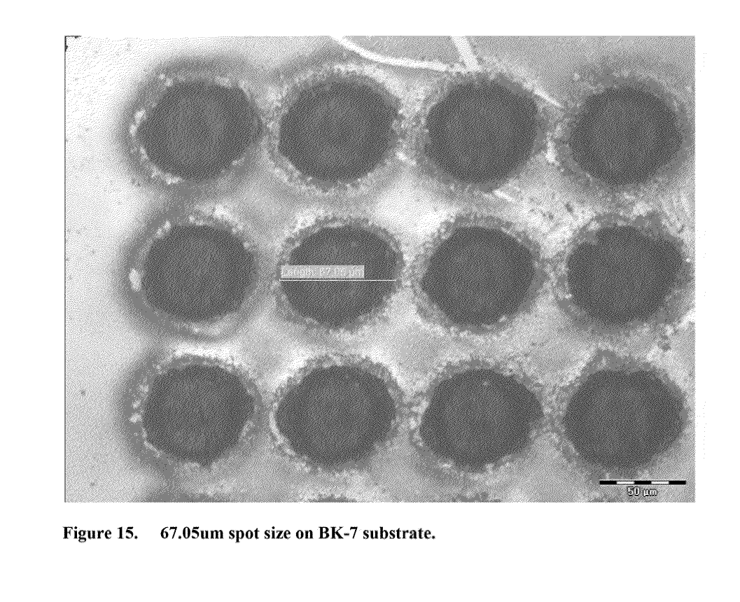

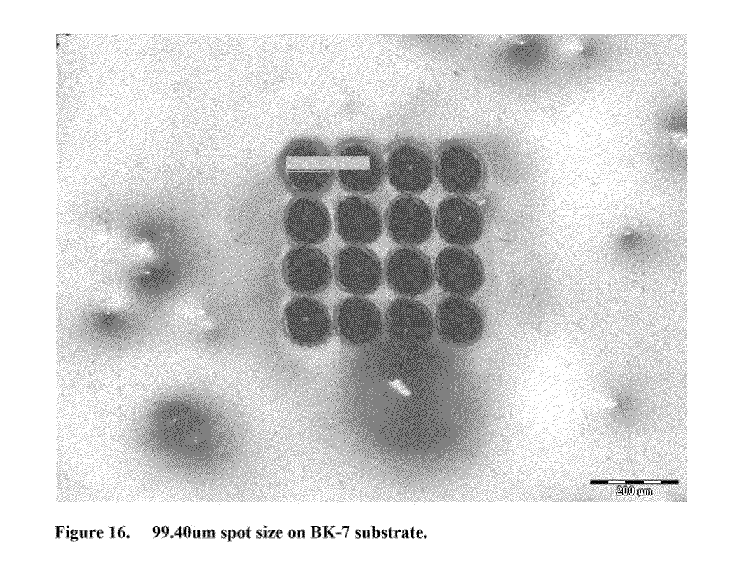

Seven images are shown (FIGS. 10-16) to show proof of concept for this technology. Various lines and dot sizes were directly written onto glass and metallic substrates using the setup shown in FIG. 1.

5. Conclusion:

The hypothesis was met in that the Ti:Sapphire laser was able to impart etchings, on a typical glass panel, of dot matrix gratings or line gratings without causing thermal or other damage to the area surrounding the dot and line matrixes.

I claim:

1. A method of fabricating a solar cell panel with a modified improved glass panel, the method comprising:
exposing a portion of a glass panel to a Ti:sapphire laser; and
etching one or more holographic grating configurations on a first layer in a particular design using said Ti:sapphire laser.

2. The method of claim 1 wherein said first layer in the front outside surface of a glass panel.

3. The method of claim 1 further comprising a second layer of holographic grating configurations etched in the back inside surface of the glass panel.

4. The method of claim 1 further comprising one or more layers of holographic grating configurations etched within the body of the glass panel.

5. The method of claim 1 wherein the one or more holographic grating configurations are etched is a substantial circular design with a specific depth.

6. The method of claim 1 wherein the one or more holographic grating configurations are etched is a substantial line design with a specific depth.

7. The method of claim 5 wherein one of more circular grating configurations are etched in the first front surface, the second inside surface, or with the one or more body layers of the glass panel.

8. The method of claim 6 wherein one of more line holographic grating configurations are etched in the first front surface, the second inside surface, or with the one or more body layers of the glass panel.

9. A modified glass panel for a solar cell panel comprising one or more layers of holographic gratings etched into the glass panel by a laser means.

10. A modified solar panel comprising at least one solar cell and a holographic means embedded within a glass panel, said holograph means designed to deflect infrared and near infrared wavelengths, said holographic means incorporated by a laser means.

11. A modified solar panel comprising at least one solar cell and a holographic means embedded within a glass panel, said holograph means designed to focus visible light wavelengths adapted to the light absorption and photovoltaic conversion characteristics of said at least one solar cell, said holographic means incorporated by a laser means.
